(19) United States
(12) Patent Application Publication
(10) Pub. No.: US 2026/0147035 A1
(43) Pub. Date: May 28, 2026

(54) METHOD OF ANALYZING INTEGRATED CIRCUIT AND PACKAGE CHIP

(71) Applicant: TAIWAN SEMICONDUCTOR MANUFACTURING COMPANY LTD., HSINCHU (TW)

(72) Inventors: YU-HAO CHEN, HSINCHU CITY (TW); KAZUYUKI TATEISHI, HSINCHU (TW); HUI YU LEE, HSIN-CHU CITY (TW); ROU SHIUAN SHEN, HSINCHU (TW); PRIYANKA RAVINDRA JADHAV, HSINCHU COUNTY (TW)

(21) Appl. No.: 18/956,038

(22) Filed: Nov. 22, 2024

(51) Int. Cl. G01R 31/28

(52) U.S. Cl. CPC G01R 31/287; G01R 31/2874; G01R 31/2879

(57) ABSTRACT

A method of analyzing an integrated circuit (IC) is provided. An original netlist of the IC is obtained according to a layout and a schematic of the IC. A first simulation is performed with the original netlist to obtain electrical properties of devices in the IC. A thermal analysis is performed on the IC according to the electrical properties, to obtain a localized temperature parameter of each of the devices. A second simulation is performed according to the original netlist and the localized temperature parameter of each of the devices. The localized temperature parameter of each of the devices is determined according to a voltage and a current of the device during the first simulation.

### BACKGROUND

In recent years, optical signaling and processing have gained prominence, particularly due to the increasing use of optical fiber technologies for signal transmission. Typically, optical signaling and processing are integrated with electrical signaling and processing to create comprehensive applications. For example, the optical fibers are often employed for long-distance signal transmission, while the electrical signals are utilized for short-distance transmission, processing, and control. Accordingly, devices that incorporate both optical and electrical components have been developed to facilitate the conversion between optical and electrical signals, as well as to process these signals. As a result, packages may include both optical (photonic) dies with the optical devices and electronic dies with the electronic devices.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or decreased for clarity of discussion.

FIG. 1 is a schematic diagram showing an IC manufacturing system in accordance with some embodiments of the present disclosure.

FIG. 2 is a schematic diagram of a system implemented in the design house of FIG. 1, in accordance with some embodiments of the present disclosure.

FIG. 3 is a cross-sectional view of a silicon photonics (SiPh) structure, in accordance with some embodiments of the present disclosure.

FIG. 4 illustrates a perspective view of the photonic device and the heater of FIG. 3, in accordance with some embodiments of the present disclosure.

FIG. 5 is a flowchart of a method of analyzing a package chip in a system level, in accordance with some embodiments of the present disclosure.

FIG. 6 illustrates multiple stages of a method of adjusting a layout of two heaters during the impact region analysis, in accordance with some embodiments of the present disclosure.

FIG. 7 illustrates a slicing operation, in accordance with some embodiments of the present disclosure.

FIG. 8 illustrates a physical parameter analysis map of the heater and the photonic device of FIG. 4, in accordance with some embodiments of the present disclosure.

FIG. 9 illustrates a product development kit (PDK) parameter table of a micro-ring modulator (MRM) in the physical extraction database, in accordance with some embodiments of the present disclosure.

FIG. 10 illustrates simulation results of an original netlist and a back-annotated netlist.

FIG. 11 illustrates an original netlist and a back-annotated netlist of a waveguide, in accordance with some embodiments of the present disclosure.

### DETAILED DESCRIPTION

The following disclosure provides many different embodiments, or examples, for implementing different features of the provided subject matter. Specific examples of components and arrangements are described to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

While embodiments of the present disclosure are discussed in detail, it should be appreciated that the present disclosure provides many applicable inventive concepts that can be embodied in a wide variety of specific contexts. The specific embodiments discussed are merely illustrative and do not limit the scope of the disclosure.

Further, spatially relative terms, such as “beneath”, “below”, “lower”, “above”, “upper”, “lower”, “left”, “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As will be appreciated by one skilled in the art, the embodiments of the present disclosure may be implemented as a system, method, or computer program product. Accordingly, the embodiments of the present disclosure may take the form of an embodiment included entirely of hardware, an embodiment included entirely of software (including firmware, resident software, micro-code, etc.) or an embodiment combining software and hardware aspects. The various types of embodiments mentioned may all generally be referred to herein as a “circuit”, “block”, “module” or “system”. Furthermore, the embodiments of the present disclosure may take the form of a computer program embodied in any tangible medium of expression having program codes embodied in the medium and executable by a computer.

The terms “reticle”, “photomask” and “mask” used throughout the present disclosure refer to a device used in a lithography operation, in which an opaque image according to a circuit pattern is formed on a substrate plate. The substrate plate may be transparent. The image of the circuit pattern on the reticle is transferred to a substrate or a wafer through a radiation source of the lithography operation. Radiation from the radiation source may be incident on the substrate via the reticle in a transmissive or reflective manner.

The terms “layout”, “design layout” and “mask layout” used throughout the present disclosure refer to a representation of an integrated circuit (IC) in terms of geometric patterns which correspond to the features of the IC, such as a metal layer, a dielectric layer, or a semiconductor layer, that make up the components of the IC. In some examples, the terms “layout”, “design layout” and “mask layout” refer to a data file including machine-readable codes or text strings that can be converted into the geometric patterns. Additional information, such as parameters extracted from the geometric patterns, in relation to the IC may be included in the layout or design layout for enhancing the design and manufacturing processes of the IC.

Embodiments of methods for analyzing an integrated circuit (IC) and a package chip in the system level is provided. According to electrical properties of the devices in one or multiple dies obtained during a post-layout simulation with a post-layout netlist, a thermal analysis and a stress analysis are performed on each device of the IC, so as to obtain the localized physical parameters for each device. The localized physical parameters are back-annotated to the physical extraction database, so as to generate a back-annotated netlist for subsequent simulations, thereby obtaining more accurate simulation results for the IC. Furthermore, an impact region analysis is performed to adjust and update the layout of the device having a larger margin for the physical parameters, so as to improve the area utilization.

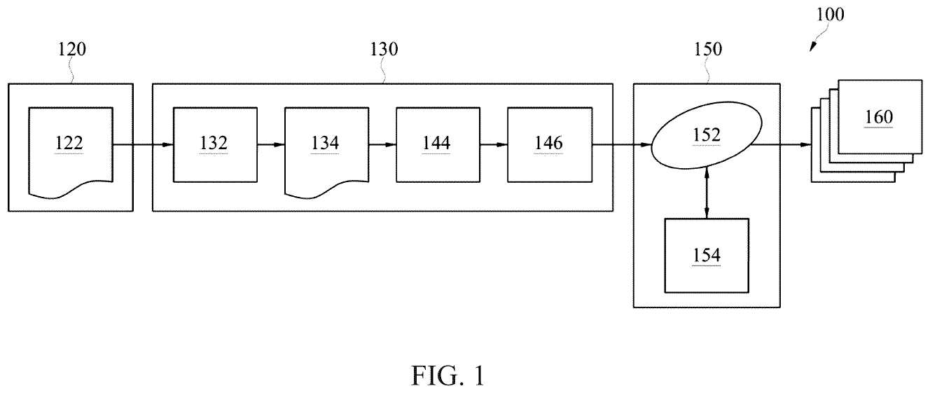

FIG. 1 is a schematic diagram showing an IC manufacturing system 100 in accordance with some embodiments of the present disclosure. The IC manufacturing system 100 is configured to manufacture an IC device (die or chip) 160 through a plurality of entities, such as a design house 120, a mask house 130, and an IC manufacturer (fab or foundry) 150. The entities in the IC manufacturing system 100 are linked by a communication channel, e.g., a wired or wireless channel, and interact with one another through a network, e.g., an intranet or the internet. In some embodiments, the design house 120, the mask house 130 and the IC manufacturer 150 belong to a single entity or are operated by independent parties.

The design house (or design team) 120 generates a design layout 122 in an IC design phase for the IC devices 160 to be fabricated. The design layout 122 includes descriptions of various geometrical patterns designed for performing specific functions that conform to the performance and manufacturing specifications. The geometrical patterns represent circuit features in the fabricated IC devices 160, e.g., metal layers, dielectric layers, or semiconductor layers, that form various IC components, such as an active region, a gate electrode, a source region or a drain region, and a conductive line or via of an interconnect structure (sometimes referred to as a redistribution layer). In an embodiment, the design house 120 operates a circuit design procedure to generate the design layout 122. The circuit design procedure may include, but is not limited to, logic design, physical design, pre-layout simulation, placement and routing, timing analysis, parameter extraction, design rule check and post-layout simulation. The design layout 122 may be converted from description texts into their visual equivalents to show a physical layout of the depicted patterns, such as the dimensions, shapes and locations thereof. In some embodiments, the design layout 122 can be expressed in a suitable file format such as GDSII, DFII, Oasis or the like.

The mask house 130 receives the design layout 122 from the design house 120 and manufactures one or more masks according to the design layout 122. In an embodiment, the mask house 130 includes a mask data preparation block 132, a mask fabrication block 144 and a mask inspection block 146. The mask data preparation block 132 modifies the design layout 122 so that a resulting design layout 134 can allow a mask writer to transfer the design layout 122 to a writer-readable format. Generally, the design layout 134 may include replicated cells thereon. When a mask with a mask pattern is formed, it is repeatedly used to transfer the patterns of the cells to a semiconductor wafer, wherein the pattern transfer is done with an exposure field in each shot. In addition, scribe line regions or test structures may be formed in spaces between the exposure fields. In some embodiments, the mask data preparation block 132 is configured to determine the locations of dies that are to be included in a cell, the locations and widths of scribe line regions around the cells, and the locations and types of test structures to be formed in the scribe line regions.

The mask fabrication block 144 is configured to form a mask with a mask pattern by preparing a substrate based on the design layout 134 provided by the mask data preparation block 132. A mask substrate is exposed to a radiation beam, such as an electron beam, based on the pattern of the design layout 134 in a writing operation, which may be followed by an etching operation to leave behind the patterns corresponding to the design layout. In an embodiment, the mask fabrication block 144 introduces a checking procedure to ensure that the layout data complies with requirements of a mask writer and/or a mask manufacturer and that the layout data can be used to generate the mask (photomask or reticle) as desired. An electron-beam (e-beam), multiple e-beams, an ion beam, a laser beam or other suitable writer source may be used to transfer the patterns. As a result, the patterns of the cells as acquired are transferred to a semiconductor substrate (such as a wafer) or material layers disposed on the semiconductor substrate. Moreover, the mask can be fabricated in various technologies. In an embodiment, the mask is fabricated using binary technology in which a binary mask includes a transparent substrate (e.g., fused quartz) and an opaque material (e.g., chromium) coated on the opaque regions of the mask. In another example, the mask is fabricated using a phase shift technology, e.g., a phase shift mask (PSM).

After the mask is fabricated, the mask inspection block 146 inspects the fabricated mask to determine if any defects, such as full-height and non-full-height defects, exist in the fabricated mask. If any defects are detected, the mask may be cleaned or the design layout in the mask may be modified.

The IC manufacturer 150 is an IC fabrication entity that includes multiple manufacturing facilities for the fabrication of a variety of different IC products. The IC manufacturer 150 uses the mask fabricated by the mask house 130 to fabricate a semiconductor wafer 152 having a plurality of IC devices 160 thereon. The semiconductor wafer 152 may include a silicon substrate or another suitable substrate including various layers formed thereon. In an embodiment, the IC manufacturer 150 includes a wafer testing block 154 configured to ensure that the IC conforms to physical manufacturing specifications and mechanical and/or electrical performance specifications. In some embodiments, the test structures formed on the semiconductor wafer 152 may be utilized to generate test data indicative of the quality of the semiconductor wafer 152. After the semiconductor wafer 152 passes the testing procedure performed by the wafer testing block 154, the semiconductor wafer 152 may be diced (or sliced) along the scribe line regions to form separate IC devices 160. The dicing process can be accomplished by scribing and breaking, by mechanical sawing (e.g., with a dicing saw) or by laser cutting.

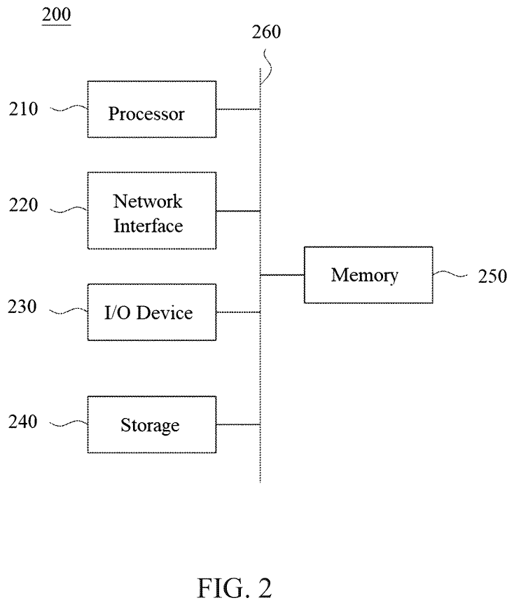

FIG. 2 is a schematic diagram of a system 200 implemented in the design house 120 of FIG. 1, in accordance with some embodiments of the present disclosure.

The system 200 includes a processor 210, a network interface 220, an input and output (I/O) device 230, a storage device 240, a memory 250, and a bus 260. The bus 260 couples the network interface 220, the I/O device 230, the storage device 240, the memory 250 and the processor 210 to each other.

The processor 210 is configured to execute program instructions that include a tool configured to perform the method as described and illustrated with reference to figures of the present disclosure. Accordingly, the tool is configured to execute operations, such as performing design, analysis and simulation operations and so on.

The network interface 220 is configured to access program instructions and data accessed by the program instructions stored remotely through a network (not shown).

The I/O device 230 includes an input device and an output device configured for enabling user interaction with the system 200. In some embodiments, the input device includes, for example, a keyboard, a mouse, and other devices. Moreover, the output device includes, for example, a display, a printer, and other devices.

The storage device 240 is configured to store program instructions and data accessed by the program instructions. In some embodiments, the storage device 240 includes a non-transitory computer-readable storage medium, for example, a magnetic disk and an optical disk.

The memory 250 is configured to store program instructions to be executed by the processor 210 and data accessed by the program instructions. In some embodiments, the memory 250 includes any combination of a random-access memory (RAM), some other volatile storage device, a read-only memory (ROM), and some other non-volatile storage device.

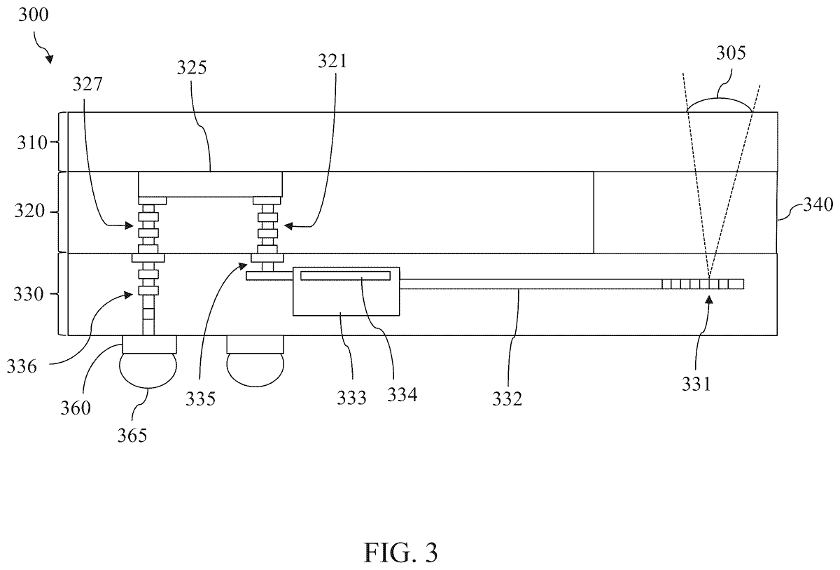

FIG. 3 is a cross-sectional view of a silicon photonics (SiPh) structure 300, in accordance with some embodiments of the present disclosure. The SiPh structure 300 of a co-packaged optics (CPO) device is formed by multiple dies in a package chip in a system level, e.g., SOIC, InFO, CoWoS, and so on. In the embodiment of FIG. 3, the SiPh structure 300 includes a supporting carrier 310, an electronic integrated circuit (EIC) 320, and a photonic integrated circuit (PIC) 330. The supporting carrier 310, the EIC 320 and the PIC 330 are vertically stacked for compact universal photonic engine (COUPE) applications.

A micro lens (or optical lens) 305 is formed on a top surface of the supporting carrier 310. In some embodiments, the supporting carrier 310 may include Si, Si₃N₄ or SiO₂. In some embodiments, the supporting carrier 310 is made from a translucent material so that the optical signals (or the light signals) from the micro lens 305 can be transmitted through the supporting carrier 310.

The SiPh structure 300 further includes a filling material 340, and the filling material 340 is formed under the micro lens 305 and at the same level as the EIC 320. In some embodiments, the filling material 340 can be filled with Si, SiO₂ or Si₃N₄ by deposition. In some embodiments, the optical signals from the micro lens 305 may penetrate through the supporting carrier 310 and the filling material 340 to the PIC 330. Furthermore, since silicon is sensitive to temperature, the filling material 340 may act as a heat sink for the EIC 320.

The PIC 330 includes a grating coupler 331, a waveguide 332, a photonic device (or component) 333 and the interconnect structures 335 and 336. The grating coupler 331 is configured to couple the optical signals from the micro lens 305 to the waveguide 332. In some embodiments, the grating coupler 331 is fabricated with a combination of silicon and polymer materials. The waveguide 332 is configured to transmit the optical signals to the photonic device 333. In the embodiment of FIG. 3, the photonic device 333 may convert the optical signals from the waveguide 332 into the electrical signals, and then the electrical signals are transmitted to the EIC 320 through the interconnect structure 335. In some embodiments, the photonic device 333 may convert the electrical signals from the interconnect structure 335 into the optical signals to be transmitted to the waveguide 332. In some embodiments, the formation processes of the grating coupler 331, the waveguide 332, and the photonic device 333 may share some common etching processes and etching masks. In some embodiments, the photonic device 333 is a device that requires heating to change the refraction index for light control, such as a micro-ring resonator (MRR), a micro-ring modulator (MRM) or a thermal phase shifter (TPh). For example, a heater 334 is adjacent to or integrated into the photonic device 333 to heat the photonic device 333.

The EIC 320 includes a device region 325 and the interconnect structures 321 and 327. The device region 325 is electrically connected to the photonic device 333 through the interconnect structures 321 and 335, and is configured to receive the electrical signals converted by the photonic device 333 and perform the operations according to the electrical signals, so as to provide the output signal to the under-bump metallization (UBM) 360 and the conductive connector 365 through the interconnect structures 327 and 336. The device region 325 includes one or more circuits formed by the active devices (e.g., field-effect transistors (FETs), bipolar-junction transistors (BJTs) and so on) and the passive devices (e.g., resistors, capacitors, diodes and so on). In some embodiments, the conductive connectors 365 may be, for example, ball grid array (BGA) connectors, solder balls, metal pillars, controlled collapse chip connection (C4) bumps, micro bumps, electroless nickel-electroless palladium-immersion gold technique (ENEPIG) formed bumps, or the like. Moreover, the conductive connector 365 may include a conductive material such as solder, copper, aluminum, gold, nickel, silver, palladium, tin, the like, or a combination thereof. In FIG. 3, the interconnect structures 321 and 327 in the EIC 320 and the interconnect structures 335 and 336 in the PIC 330 are formed by conductive vias, metallization layers and/or through-substrate-vias (TSVs).

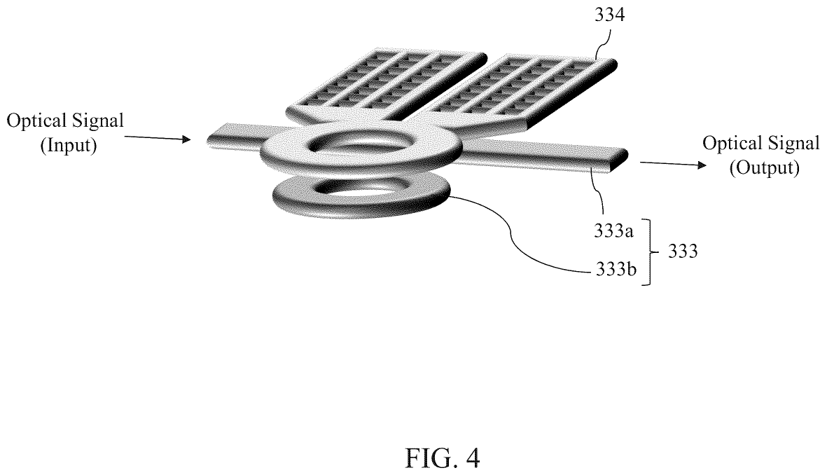

FIG. 4 illustrates a perspective view of the photonic device 333 and the heater 334 of FIG. 3, in accordance with some embodiments of the present disclosure. In the embodiment of FIG. 4, the photonic device 333 is an MRR including a silicon waveguide 333a and a ring resonator 333b. In some embodiments, the silicon waveguide 333a may be integrated with the waveguide 332 of FIG. 3. The ring resonator 336b is disposed adjacent to the silicon waveguide 333a. The ring resonator 333b is made of silicon. In some embodiments, the silicon waveguide 333a includes silicon nitride. The heater 334 is disposed over the silicon waveguide 333a and the ring resonator 333b and configured to heat up the ring resonator 333b for resonance tuning. In some embodiments, the heater 334 may be a ring-shaped heater. The heater 334 is made of a conductive material, which may include tungsten (W). In some embodiments, the heater 334 may include nichrome, FeCrAl, Cupronickel (CuNi), or any other suitable materials.

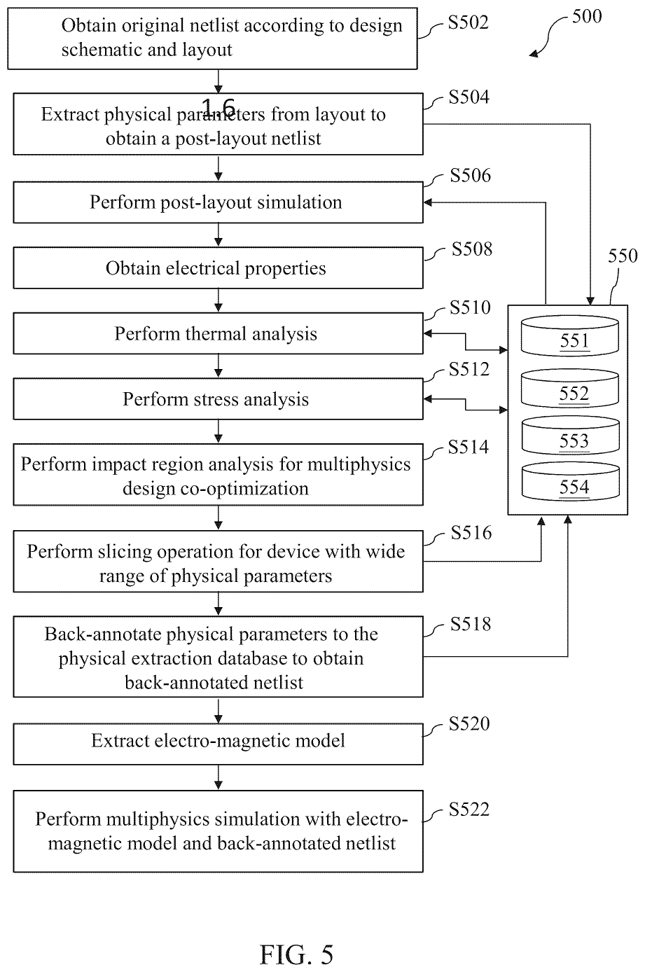

FIG. 5 is a flowchart of a method 500 of analyzing (or simulating) a package chip (e.g., a packaged device composed of multiple dies) in a system level, in accordance with some embodiments of the present disclosure. It should be understood that additional operations can be provided before, during, and after the operations shown in FIG. 5, and some of the operations described below can be replaced or eliminated in other embodiments of the method 500. The order of the operations may be interchangeable. The method 500 is implemented in a system (e.g., the system 200 of FIG. 2) in the design house 120 of FIG. 1.

In operation S502, a design schematic and a layout of each die (or IC), such as the EIC 320 and PIC 330 of FIG. 3, to be implemented in the package chip are obtained to generate an original netlist. In some embodiments, the layout includes a physical architecture representing each die in a two-dimensional circuit plane. For example, detailed structures and associated geometries for the components of the major blocks in each die are determined. Furthermore, it is required that both of placement and routing in the layout meet the requirement of a design rule check (DRC) deck so that the manufacturing constraints of each die are fulfilled. Furthermore, the original netlist along with data on placement and routing of each die is obtained accordingly.

In operation S504, a layout parameter extraction (LPE) operation is performed on each die to obtain layout-dependent parameters of the die, such as parasitic resistance and parasitic capacitance. Furthermore, a post-layout netlist, which includes the layout-dependent parameters, is generated. Moreover, the layout-dependent parameters of each die are stored in a physical extraction database 551 of a library 550. In some embodiments, the library 550 is implemented by the storage device 240 of FIG. 2. Furthermore, the layout-dependent parameters of the physical extraction database 551 correspond to physical verifications under various process corners of a corner database 552 of library 550.

In operation S506, a post-layout simulation is performed according to the post-layout netlist. For example, a simulation of transistor-level behavior is conducted to examine whether the performance of each die derived by the post-layout netlist meets the system specifications. In some embodiments, the post-layout simulation is performed to minimize probability of electrical issues or layout difficulties during the die manufacturing process. The electrical or geometric parameters of devices and other features in each die which are listed in commonly used design/simulation libraries can also be used to simulate the real-world performance of the dies.

In semiconductor manufacturing, a process corner is an example of a design-of-experiments (DoE) technique that refers to a variation of design (process) parameters used to realize an IC design onto a semiconductor wafer/substrate. Process corners represent the extremes of these parameter variations within which a circuit that has been etched onto the wafer can still function correctly. For example, each transistor may include three lumped corners: a typical corner, a fast corner, and a slow corner, which represent a typical speed of an electrical property (e.g., a carrier mobility), a fast speed of the electrical property, and a slow speed of the electrical property, respectively. Accordingly, a total of five corners may be used to describe global variations of a sub-circuit of the die: a typical-typical (TT) corner (representing a typical speed of an N-type carrier mobility and a typical speed of a P-type carrier mobility), a fast-fast (FF) corner (representing a fast speed of the N-type carrier mobility and a fast speed of the P-type carrier mobility), a slow-slow (SS) corner (representing a slow speed of the N-type carrier mobility and a slow speed of the P-type carrier mobility), a fast-slow (FS) corner (representing a fast speed of the N-type carrier mobility and a slow speed of the P-type carrier mobility), and a slow-fast (SF) corner (representing a slow speed of the N-type carrier mobility and a fast speed of the P-type carrier mobility).

In operation S508, the electrical properties of the devices of each die in the package chip are obtained according to the results of the post-layout simulation. The electrical properties of each device may include voltage, current and power of the device during the post-layout simulation. In some embodiments, the information of the electrical properties is stored in the library 550.

In operation S510, a thermal analysis is performed according to the electrical properties of the devices and material property technology files, so as to obtain a temperature map of the devices including the temperature parameters of each device (or feature). Furthermore, the resulting temperatures (e.g., the temperature parameters) are stored in a physical analysis database 554 of the library 550. The material property technology files are stored in a material property database 553 of the library 550. In some embodiments, according to the electrical properties with the material property technology files and the parasitic information of the parasitic resistance and parasitic capacitance, the power and corresponding temperature of the device/feature at its respective location are obtained, such as the power is the product of current and voltage of the feature.

In some embodiments, the material property technology files include the material property in multi-corners. For example, a wafer fabrication process may have different layer thicknesses or doping concentrations at different locations on the wafer. Typically, the central area has the most precise conditions and the edge areas have the most biased conditions. Furthermore, in the material property technology files, a central corner technology file represents the material property in a central area of a wafer, which is a best die formation area, and an edge corner technology file represents the material property in an edge area of the wafer, which is a worst die formation area.

In operation S512, a stress analysis is performed according to the results of the thermal analysis and material property technology files, so as to obtain the stress parameter of each device. Furthermore, the resulting stresses (e.g., the stress parameters) are stored in the physical analysis database 554. In some embodiments, the stress of the device/feature is analyzed according to the material properties of the device/feature from the material property technology files, such as coefficient of thermal expansion (CTE), and the resulting temperature in operation S510. Thermal creates localized stresses due to the material property (e.g., CTE), so thermal and stress are correlated parameters. For example, CTE differences cause localized warpage and induce stress.

In operation S514, an impact region analysis is performed for multiphysics design co-optimization. An impact boundary of each device is defined according to the specifications. Furthermore, the impact boundary of the thermal analysis can be defined based on the temperature, and the impact boundary of the stress analysis can be defined based on the pressure. According to the results of impact region analysis, the layout of the device with a margin greater than the area defined by the impact boundary can be adjusted and updated, to improve the area utilization. For example, assuming that a first device has a first area defined by its impact boundary and a second device closest to the first device has a second area defined by its impact boundary, when a distance from a center of the first device to the second area of the second device (e.g., the margin of the first device) is greater than a distance from the center to the first area of the first device, the first device is moved closer to the second device and then the corresponding layout is adjusted and updated. The adjusted layout is updated to a layout database (not shown) to improve power-performance-area (PPA) optimization. For example, a device/feature is moved closer to other device/feature when the impact boundary of the device/feature does not overlap the impact boundary of other device/feature according to the results of the thermal analysis.

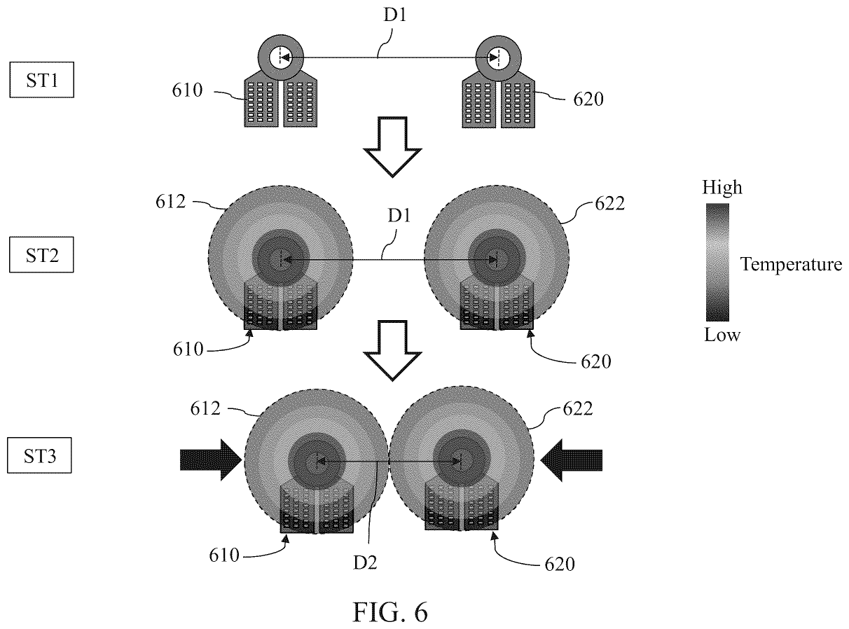

FIG. 6 illustrates multiple stages of a method of adjusting a layout of two heaters 610 and 620 during the impact region analysis, in accordance with some embodiments of the present disclosure. In stage ST1, an original layout of the heaters 610 and 620 is shown, i.e., the layout obtained in operation S502, and a distance between the center of the heater 610 and the center of the heater 620 is a first distance D1. In stage ST2, the impact regions of the heaters 610 and 620 corresponding to the thermal analysis are shown. The temperature spreads and decreases from the center toward the perimeter of each of the heaters 610 and 620 in a concentric pattern, as shown in temperature distribution plots 612 and 622. The outermost boundary of temperature distribution plots 612/622 is defined as the impact boundary. Since there is a more than enough margin between the impact boundaries of the heaters 610 and 620, the first distance D1 between the heaters 610 and 620 is shortened to a second distance D2, i.e., the heaters 610 and 620 are made closer. In some embodiments, the second distance D2 is the minimum distance such that the temperature distribution plot 612 does not overlap the temperature distribution plot 622. Accordingly, the layout (or location) of the photonic devices or related features corresponding to or overlapping the heaters 610 and 620 are also be adjusted.

Referring back to operation S516 of FIG. 5, a slicing operation is performed for the device/feature with wide range of physical parameters. For a device having a temperature or stress distribution with a relatively large temperature or pressure span between the boundaries and the center, the device is divided into multiple sub-devices each having a smaller temperature or stress span. For example, if there is a large span in the range of physical parameter between the boundaries and the center, the device is sliced in half until the gap is small enough.

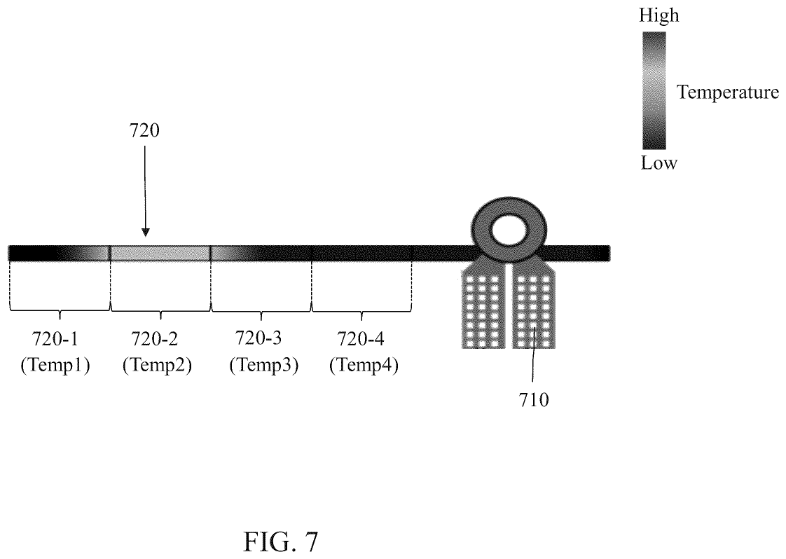

FIG. 7 illustrates the slicing operation, in accordance with some embodiments of the present disclosure. A waveguide 720 overlapping a heater 710 has a large temperature distribution span, and the temperature of a portion of the waveguide 720 becomes higher as such portion is made closer to the heater 710. In the embodiment of FIG. 7, the temperature difference between the two ends of the waveguide 720 is hundreds of degrees, and the slicing operation is performed on the waveguide 720, so as to divide the waveguide 720 into the sub-waveguides 720-1 through 720-4 with the corresponding temperature parameters Temp1 through Temp4, where Temp4>Temp3>Temp2>Temp1. Each of the sub-waveguides 720-1 through 720-4 is a segment of the waveguide 720, and has a more uniform temperature distribution, i.e., the temperature difference between the two ends of each sub-waveguide is smaller than a threshold value. In some embodiments, the threshold value is determined according to the impact boundary. After the slicing operation is performed, the layout, schematic, and netlist of the waveguide 720 are automatically adjusted and updated to be represented by the sub-waveguides 720-1 through 720-4, and the physical extraction database 551 is updated accordingly. In other words, the netlist, the layout, and the schematic are adjusted to replace the waveguide 720 with the sub-waveguides 720-1 through 720-4. In some embodiments, the slicing operation is an optional operation and can be omitted in method 500.

Referring back to operation S518 of FIG. 5, the physical parameters of each device/feature are back-annotated to the physical extraction database 551. For example, the information of temperature and stress of the devices are back-annotated to the physical extraction database 551. In some embodiments, the device/feature may have multiple layers in the physical analysis database, and the physical parameters in each layer are analyzed and saved in the physical analysis database 554 during the operations S510 and S512. Furthermore, the physical parameters (e.g., the temperature parameter and the stress parameter) in each layer are also back-annotated to the physical extraction database 551. In some embodiments, only the physical parameters in the specific layer assigned by the user are analyzed, saved and back-annotated.

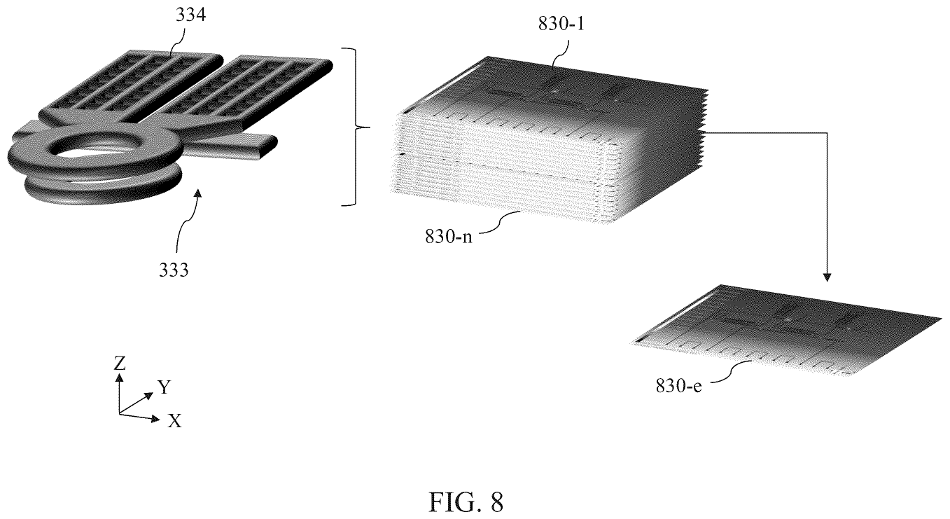

FIG. 8 illustrates a physical parameter analysis map of the heater 334 and the photonic device 333 of FIG. 4, in accordance with some embodiments of the present disclosure. The physical parameter analysis map of the heater 334 and the photonic device 333 includes temperature or stress parameters of the heater 334 and the photonic device 333, and may be located (or divided) with X, Y, Z coordination. For example, the heater 334 and the photonic device 333 may divided into multiple layers 830-1 through 830-n in Z-axis. In the embodiment of FIG. 8, a layout of the heater 334 and the photonic device 333 can be represented by the plane of the X and Y axes, and the Z axis represents the direction perpendicular to the layout. In some embodiments, the physical parameters in each of the layers 830-1 through 830-n are back-annotated to the physical extraction database 551. In some embodiments, according to user selection, the physical parameters of the layer 830-e selected by the user are back-annotated to the physical extraction database 551. In the physical extraction database 551, the back-annotated physical conditions may be shown using a process design kit (PDK).

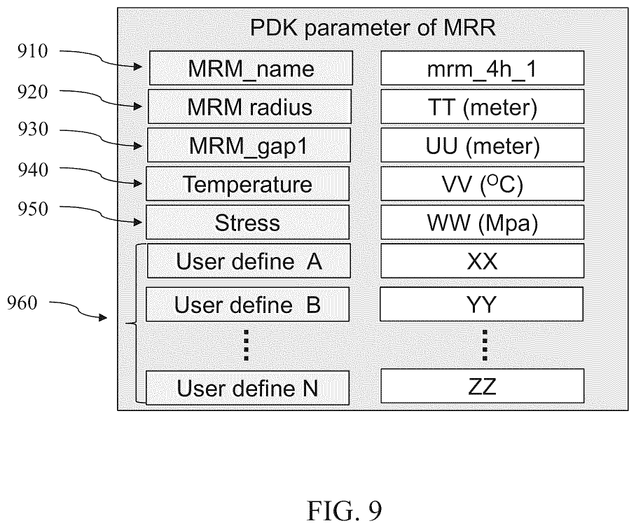

FIG. 9 illustrates a PDK parameter table of an MRM in the physical extraction database 551, in accordance with some embodiments of the present disclosure. The field 910 represents the name or type of the MRR in netlist. The field 920 represents the radius of the MRR. The field 930 represents a gap between the micro-ring part (e.g., the ring resonator 333b in FIG. 4) of the MRR and the waveguide part (e.g., the silicon waveguide 333a in FIG. 4) of the MRR. The field 940 represents the temperature parameter of the MRM obtained in the thermal analysis of operation S510. The field 950 represents the stress parameter of the MRM obtained in the stress analysis of operation S512. The fields 960 represents the new physical parameters created by the user through the interactive interface (e.g., the I/O device 230 of FIG. 2). The fields 910-960 of the PDK parameter table will be output as a back-annotated netlist of the MRM with multiphysics parameters or other format data/file for subsequent simulation.

Referring back to operation S520 of FIG. 5, an electro-magnetic model is extracted for the package chip according to the physical extraction database 551 having the back-annotated physical conditions (hereinafter referred to as the back-annotated physical extraction database 551). Compared with the thermal and stress parameters, the electro-magnetic parameter is an independent parameter that is not correlated to other physical parameters. The electro-magnetic extraction (or analysis) may be performed independently at any stage of method 500. For example, the electro-magnetic extraction in operation S520 may be moved from between operations S518 and S522 to between operations S504 and S506.

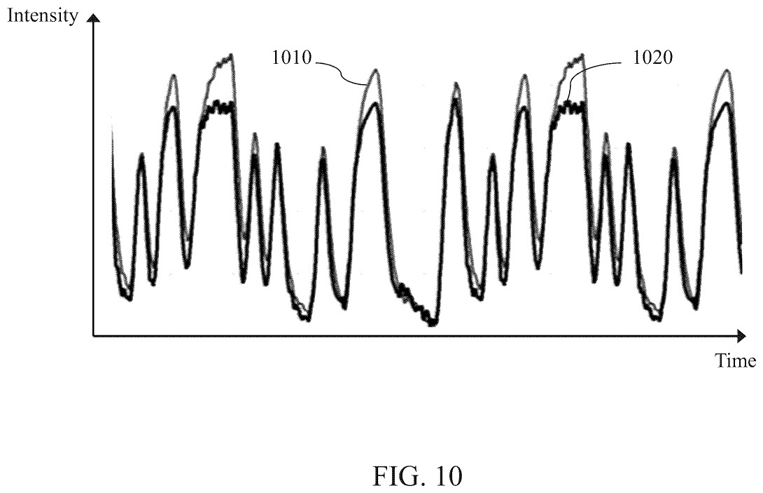

In operation S522, a multiphysics simulation is performed with the electro-magnetic model and the back-annotated physical extraction database 551 based on the netlist having the multiphysics parameters (or referred as the back-annotated netlist). The multiphysics simulation is a post-layout simulation associated with the multiphysics parameters. During this simulation, the physical parameters (e.g., temperature and stress parameters) of each device are considered, so as to obtain more accurate simulation results than the post-layout simulations (e.g., the post-layout simulation in operation S506) that do not take individual physical parameters (i.e., layout-independent but electrically relevant physical parameters) into account, such as the devices are simulated at the same temperature. As shown in FIG. 10, curve 1010 represents a simulation result of a MRM with the original netlist under a universal temperature for all devices, and curve 1020 represents a simulation result of the MRM with the back-annotated netlist under a localized temperature. The curve 1020 has the accurate intensity than the curve 1010.

After the multiphysics simulation is completed and the results of the multiphysics simulation meet the system specifications (e.g., performance analysis in power, signal and timing integrity), the design layout 122 of each die is generated according to the adjusted layout updated in the layout database (not shown), and then the dies (e.g., IC device 160) are manufactured. Next, the dies are packaged to form the package chip.

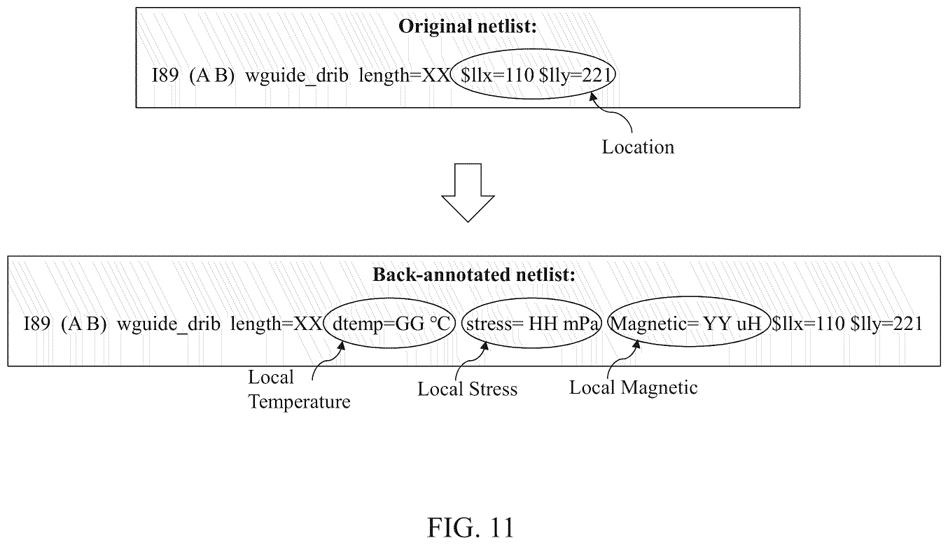

FIG. 11 illustrates an original netlist and a back-annotated netlist of a waveguide, in accordance with some embodiments of the present disclosure. In the original netlist, the waveguide is named “wguide_drib” and is connected between the device (or net) A and the device (or net) B. The length of the waveguide is “XX”. Furthermore, the X and Y coordinates of the waveguide on the layout are 110 and 221, respectively. Compared with the original netlist, the back-annotated netlist further includes the physical parameters, such as the localized temperature, stress and magnetic of the waveguide. Thus, the simulator (e.g., HSPICE, SPICE, SPECTRE, etc.) can take the physical parameters into the simulation to obtain more accurate simulation results.

According to some embodiments, a method of analyzing an integrated circuit (IC) is provided. An original netlist of the IC is obtained according to a layout and a schematic of the IC. A first simulation is performed with the original netlist to obtain electrical properties of devices in the IC. A thermal analysis is performed on the IC according to the electrical properties, to obtain a localized temperature parameter of each of the devices. A second simulation is performed according to the original netlist and the localized temperature parameter of each of the devices. The localized temperature parameter of each of the devices is determined according to a voltage and a current of the device during the first simulation.

According to some embodiments, a method of analyzing a package chip is provided. An original netlist of the package chip is obtained according to layout and schematic of each of dies to be packaged in the package chip. A first post-layout simulation is performed with the original netlist to obtain electrical properties of devices in each of the dies. One or more localized physical parameters of each of the devices are obtained according to the electrical properties. A second post-layout simulation is performed according to the original netlist and the one or more localized physical parameters of each of the devices. A first die of the dies includes an electronic integrated circuit (EIC), and a second die of the dies includes a photonic integrated circuit (PIC).

According to some embodiments, a method of analyzing an integrated circuit (IC) is provided. A plurality of physical parameters are extracted from a layout of the IC. A first simulation is performed based on a first netlist having the physical parameters to obtain a current and a voltage of each device in the IC. A temperature parameter of each device is obtained according to the current and the voltage of each device. The temperature parameter of each device are added into the first netlist to obtain a second netlist. A second simulation is performed based on the second netlist. The physical parameters are layout-dependent parameters including parasitic resistance and parasitic capacitance in the layout of the IC.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of analyzing an integrated circuit (IC), comprising:
obtaining an original netlist of the IC according to a layout and a schematic of the IC;
performing a first simulation with the original netlist to obtain electrical properties of devices in the IC;
performing a thermal analysis on the IC according to the electrical properties to obtain a localized temperature parameter of each of the devices; and
performing a second simulation according to the original netlist and the localized temperature parameter of each of the devices,
wherein the localized temperature parameter of each of the devices is determined according to a voltage and a current of the device during the first simulation.

2. The method of claim 1, further comprising:
performing a stress analysis on the IC according to the localized temperature parameter of each of the devices to obtain a localized stress parameter of each of the devices.

3. The method of claim 2, wherein performing the second simulation according to the
original netlist and the localized temperature parameter of each of the devices further comprises:
providing a back-annotated netlist according to the original netlist, the localized temperature parameter and the localized stress parameter of each of the devices; and
performing the second simulation with the back-annotated netlist including the original netlist.

4. The method of claim 1, further comprising:
performing an impact region analysis according to the localized temperature parameter of each of the devices and an impact boundary based on the thermal analysis; and
adjusting a layout of at least one of the devices when the at least one of the devices has a margin greater than an area defined by the impact boundary in the layout of the IC.

5. The method of claim 4, wherein adjusting a layout of at least one of the devices when
the at least one of the devices has the margin greater than an area defined by the impact boundary in the layout of the IC further comprises:
moving the at least one of the devices closer to a first device of the IC when the impact boundary of the at least one of the devices does not overlap the impact boundary of the first device.

6. The method of claim 5, wherein the at least one of the devices and the first device are heaters.

7. The method of claim 4, wherein performing the second simulation according to the original netlist and the localized temperature parameter of each of the devices further comprises:
providing a back-annotated netlist according to the original netlist, the localized temperature parameter of each of the devices, and the adjusted layout of the at least one of the devices; and
performing the second simulation with the back-annotated netlist including the original netlist.

8. The method of claim 1, further comprising:
performing a slicing operation on one of the devices to divide the one of the devices into a plurality of sub-devices when the one of the devices has a temperature distribution span between boundaries and center of the one of the devices greater than a threshold.

9. The method of claim 8, further comprising:
adjusting the layout and the schematic of the IC to replace the one of the devices with the sub-devices.

10. The method of claim 8, wherein the one of the devices is a waveguide.

11. A method of analyzing a package chip, comprising:
obtaining an original netlist of the package chip according to layout and schematic of each of dies to be packaged in the package chip;
performing a first post-layout simulation with the original netlist to obtain electrical properties of devices in each of the dies;
obtaining one or more localized physical parameters of each of the devices according to the electrical properties; and
performing a second post-layout simulation according to the original netlist and the one or more localized physical parameters of each of the devices,
wherein a first die of the dies comprises an electronic integrated circuit (EIC), and a second die of the dies comprises a photonic integrated circuit (PIC).

12. The method of claim 11, wherein obtaining the one or more localized physical parameters of each of the devices according to the electrical properties further comprises:
performing a thermal analysis on the devices of each of the dies according to the electrical properties to obtain a localized temperature parameter of each of the devices; and
performing a stress analysis on the devices of each of the dies according to the localized temperature parameters of the devices to obtain a localized stress parameter of each of the devices.

13. The method of claim 12, wherein performing the second post-layout simulation according to the original netlist and the one or more localized physical parameters of each of the devices further comprises:
providing a back-annotated netlist according to the original netlist and the localized temperature parameter and the localized stress parameter of each of the devices of the package chip; and
performing the second post-layout simulation with the back-annotated netlist.

14. The method of claim 11, further comprising:
performing an impact region analysis according to the one or more localized physical parameters of the devices and an impact boundary corresponding to the one or more localized physical parameters; and
adjusting a layout of a first device of the devices in the second die when the layout of the first device has a margin greater than an area defined by the impact boundary.

15. The method of claim 14, wherein adjusting the layout of the first device in the second die when the layout of the first device has the margin greater than an area defined by the impact boundary further comprises:
moving the first device closer to a second device of the second die when the impact boundary of the first device does not overlap the impact boundary of the second device.

16. The method of claim 14, wherein performing the second post-layout simulation according to the original netlist and the one or more localized physical parameters of each of the devices further comprises:
providing a back-annotated netlist according to the original netlist, the one or more localized physical parameters, and the adjusted layout of the first device in the second die; and
performing the second post-layout simulation with the back-annotated netlist.

17. The method of claim 11, further comprising:
performing a slicing operation on a first device of the devices in the second die to divide the first device into a plurality of sub-devices when the first device has a large physical distribution span between boundaries and a center of the first device.

18. The method of claim 17, further comprising:
adjusting the layout and the schematic of the second die to replace the first device with the sub-devices.

19. A method of analyzing an integrated circuit (IC), comprising:
extracting a plurality of physical parameters from a layout of the IC;
performing a first simulation based on a first netlist having the physical parameters to obtain a current and a voltage of each device in the IC;
obtaining a temperature parameter of each device according to the current and the voltage of each device;
adding the temperature parameter of each device into the first netlist to obtain a second netlist; and
performing a second simulation based on the second netlist,
wherein the physical parameters are layout-dependent parameters comprising parasitic resistance and parasitic capacitance in the layout of the IC.

20. The method of claim 19, wherein obtaining the temperature parameter of each device according to the current and the voltage of each device further comprises:
dividing each device into a plurality of layers in a direction perpendicular to the layout of the IC, wherein each of the layers has a respective temperature parameter;
selecting one of the layers in each device; and
obtaining the temperature parameter of each device according to the respective temperature parameter of the selected one of the layers in each device.
